(19) United States
(12) Patent Application Publication
(10) Pub. No.: US 2005/0184794 A1
(43) Pub. Date: Aug. 25, 2005

(54) Active DC output control for active control of leakage in small geometry integrated circuits

(75) Inventors: William E. Armstrong, Redwood City, CA (US); Theodore M. Myers, Los Altos, CA (US)

Correspondence Address: Fernandez & Associates, LLP, PO Box D, Menlo Park, CA, 94026-6402, US

(73) Assignee: Summit Microelectronics, Inc., San Jose, CA (US)

(21) Appl. No.: 10/776,354

(22) Filed: Feb. 10, 2004

(51) Int. Cl. H03K 3/01

(52) U.S. Cl. 327/534

(57) ABSTRACT

Active back bias voltage, applied to wells of N-MOS and P-MOS transistors of a small geometry integrated circuit, is used to set the threshold voltages and leakage currents precisely in order to improve speed and at the same time control device sub-threshold leakage. The active back bias applies a voltage to the well of devices on the small geometry integrated circuit. The voltage with increases until the leakage current goes to a predetermined level. If the leakage increases with age, temperature, V_{DD} voltage or other conditions the bias supply from the active back bias generator compensates.

### CROSS REFERENCE TO RELATED APPLICATIONS

This application relates to a co-pending U.S. patent application Ser. No. 10/294,842, filed on Nov. 13, 2002; entitled “Active DC Output Control and Method for DC/DC Converter” by Myers et al., owned by the assignee of this application and incorporated herein by reference.

### FIELD OF THE INVENTION

Invention relates to a method for applying an active back bias voltage to NMOS or PMOS transistor well and more particularly to a method of setting the threshold voltage or the leakage current precisely in order to improve speed and control device sub-threshold leakage.

### BACKGROUND OF INVENTION

Back bias generators were used on NMOS integrated circuits for many years in order to improve performance of large geometry circuits. Many of the early NMOS products made use of a negative voltage to bias the substrate rather than simply grounding in this region. The use of substrate biasing has two benefits; first, the magnitude of this bias voltage can be automatically regulated to control the threshold voltage of the N-channel transistors because of the body effect or substrate effect on threshold voltage, which prevents an undesired shift to depletion mode. Secondly, biasing the substrate also raises the punch-through voltage of the transistors. Some NMOS products still make use of on-chip-generated substrate biasing to obtain this higher breakdown-voltage advantage.

U.S. Pat. No. 6,175,263 and U.S. Pat. No. 6,515,534 are examples of biasing schemes focused on CMOS transistors; these inventions lack many of the features and benefits of the present invention.

At geometries of 0.13 microns and below the sub-threshold source-drain leakage becomes a significant portion of the overall power consumption in CMOS circuits. Power consumption in today's integrated circuits is a major problem.

A serious problem is that sub-threshold leakage of a small geometry device creates undesired current. This leakage increases as device geometries decrease, note FIG. 1. Drive voltage is squeezed between the maximum Vt and the lowered Vdd.

As geometries shrink, junction and gate breakdown voltages lower and power supplies voltages must be reduced therefore. As supply voltage is reduced, the drive voltage margin (Vdd−Vt) is reduced unless the maximum Vt is reduced. Reducing Vt can be accomplished only by tighter and tighter process control; however zero Vt variance is not possible. Also, sub-threshold currents become more and more significant as Vt approaches zero. Finally, temperature variation of sub-threshold currents and Vt itself result in the need for additional “margin” that is simply not available in conventional circuits.

Mukhopadhyay, et al. (3) describe in detail the impact of various process variations on total leakage in scaled CMOS devices. The authors conclude that “. . . (process) parameter variation has significant impact on each leakage component . . . ”. The relationship between the threshold voltage, Vt, and sub-threshold leakage, Isub, as a function of various device parameters is detailed in this paper.

### SUMMARY OF INVENTION

Invention resides in actively applying a back bias voltage to wells of N-MOS and P-MOS transistors of small geometry integrated circuits while sensing the sub-threshold leakage current of a reference transistor in the respective well. The active back bias voltage is used to set the threshold voltages or leakage currents precisely in order to improve speed and at the same time control device sub-threshold leakage. The active back bias generator dynamically supplies a voltage to the well of devices on the integrated circuit. The back bias voltage supplied changes until the sub-threshold leakage current reaches a predetermined level and is then modulated based upon the leakage current sensed and the preset level. This means that if leakage increases with age, temperature, V_{DD} voltage, or other conditions, the bias supply from the active back bias generator will compensate.

### BRIEF DESCRIPTION OF DRAWINGS

FIG. 1 shows how leakage current increases with shrinking geometry, figuratively.

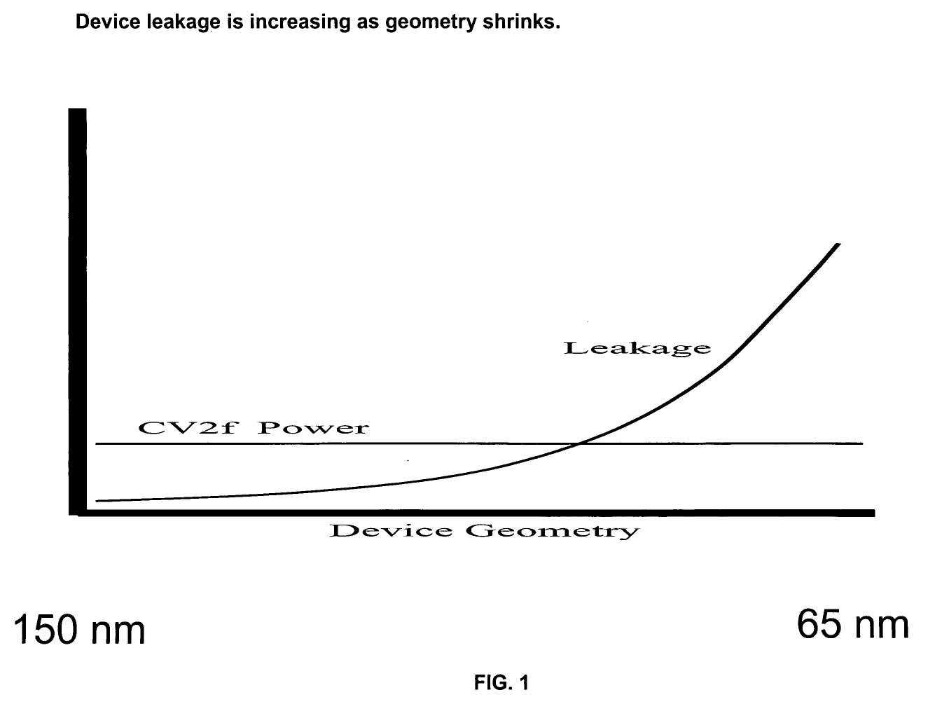

FIG. 2 figuratively shows how the power supply has ample range for a large geometry device.

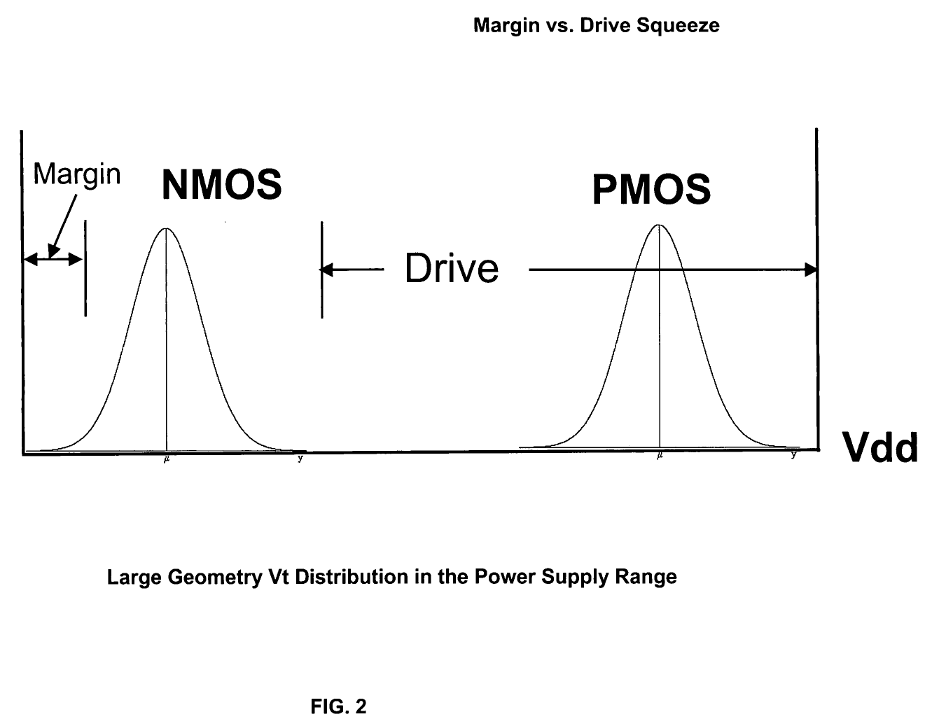

FIG. 3 figuratively shows how the power supply has reduced margin for a small geometry device.

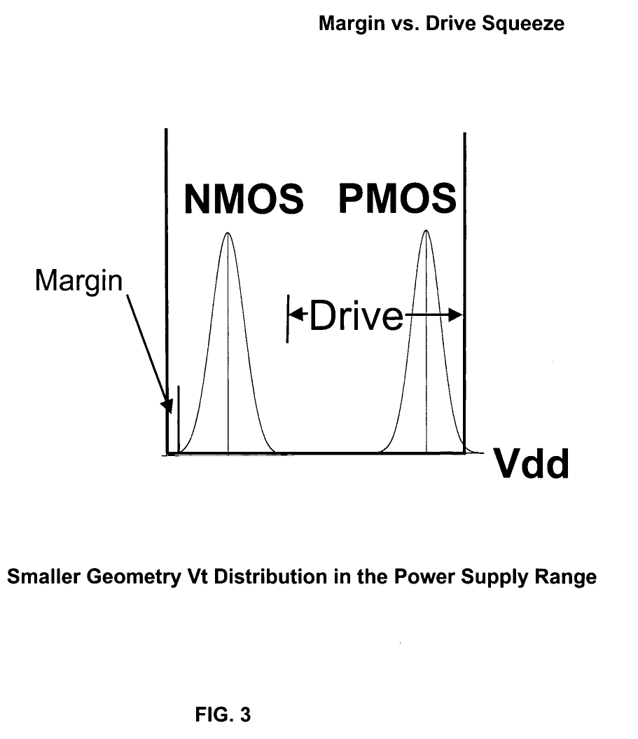

FIG. 4 figuratively shows how the power supply can have “negative margin” for a small geometry device.

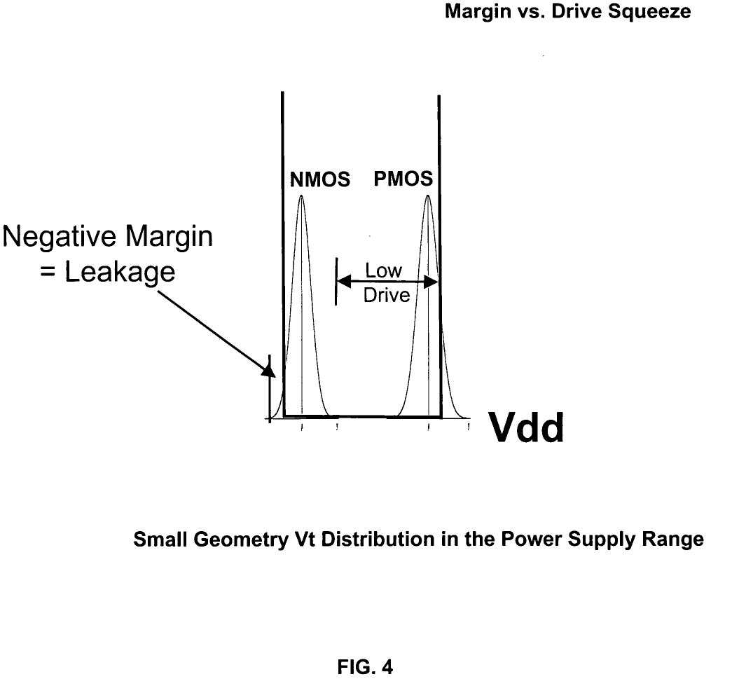

FIG. 5 figuratively shows how a “passive back bias” solution would improve the leakage but not the Vt distribution for a small geometry device.

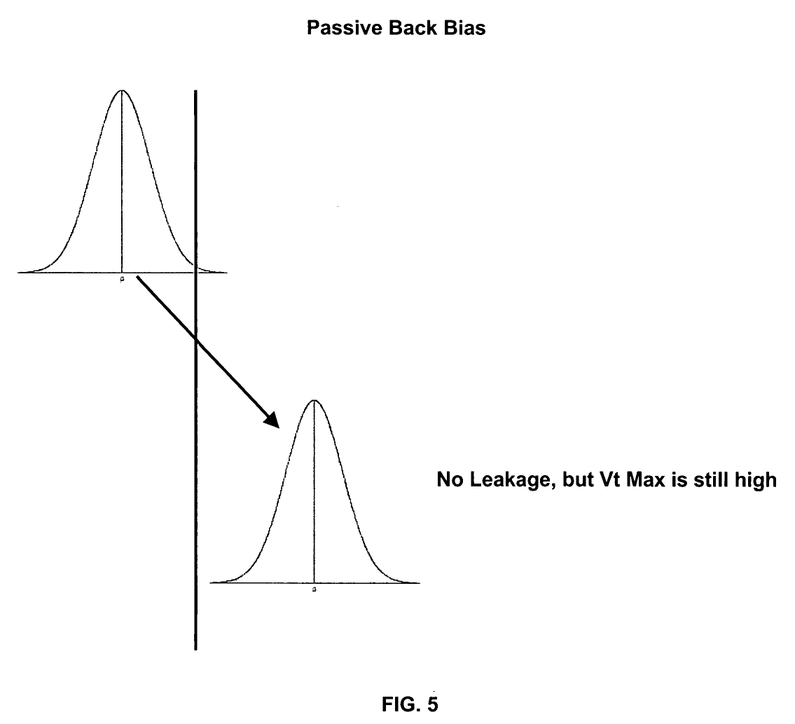

FIG. 6 figuratively shows how a “one bit active back bias” solution improves the leakage and some but insufficient improvement on the Vt distribution for a small geometry device.

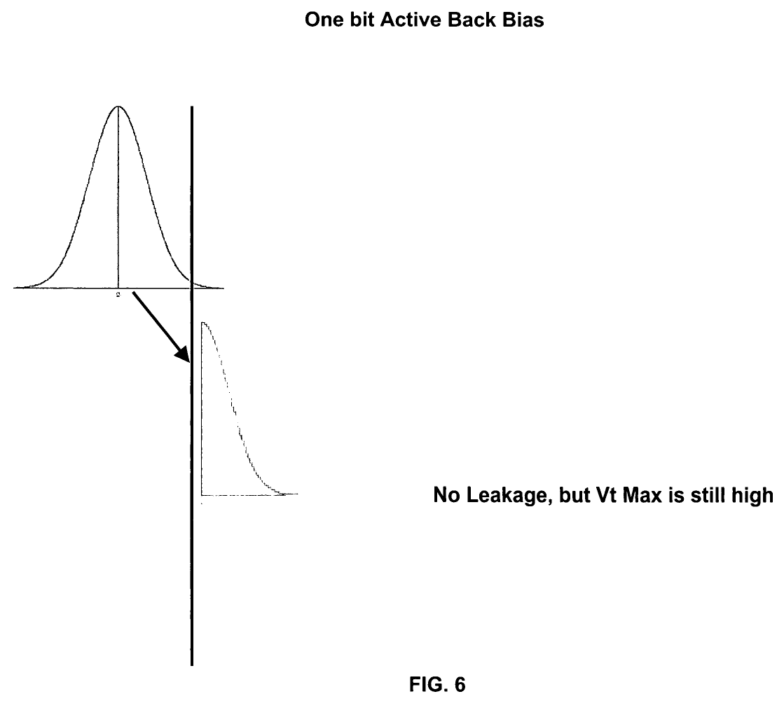

FIG. 7 figuratively shows how a “N-bit active back bias” solution improves the leakage and improves the Vt distribution greatly for a small geometry device.

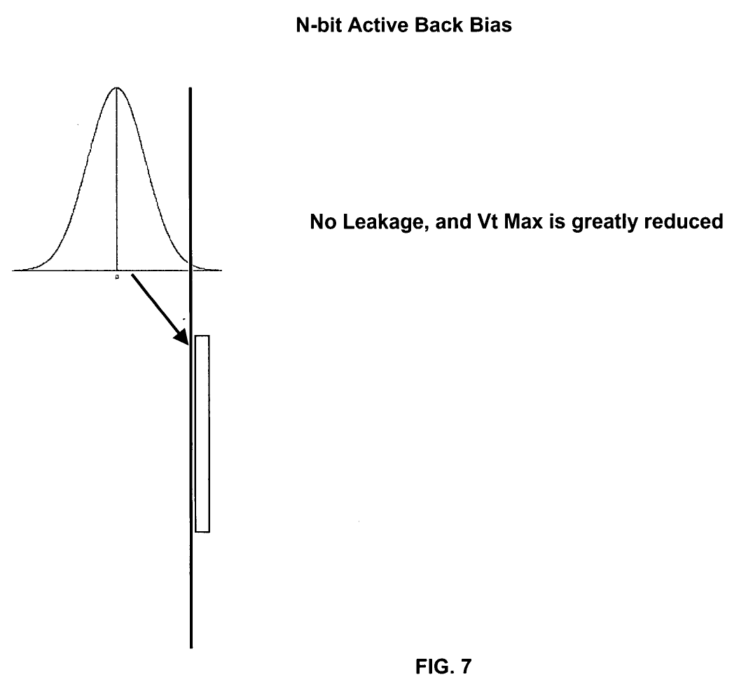

FIG. 8 figuratively shows a typical Vt distribution for small geometry devices with the drive margin indicated.

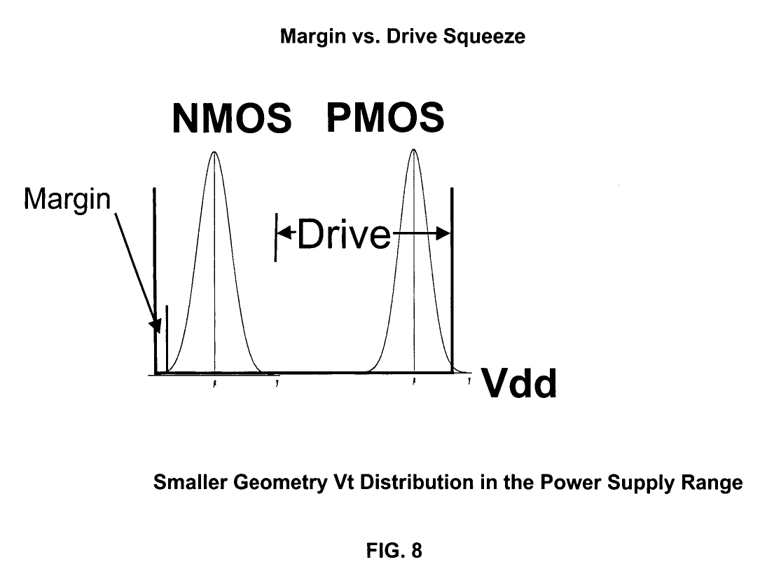

FIG. 9 figuratively shows a typical Vt distribution for small geometry devices with the drive margin indicated when a N-bit active back bias capability has been added to the circuit.

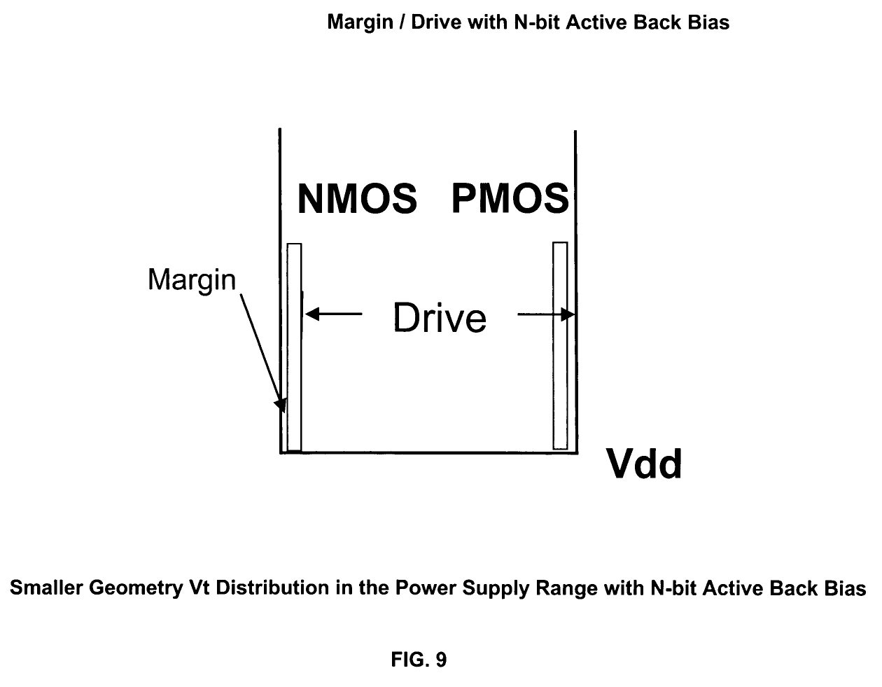

FIG. 10 is general system block diagram for implementing present invention on a reference PMOS and NMOS transistor.

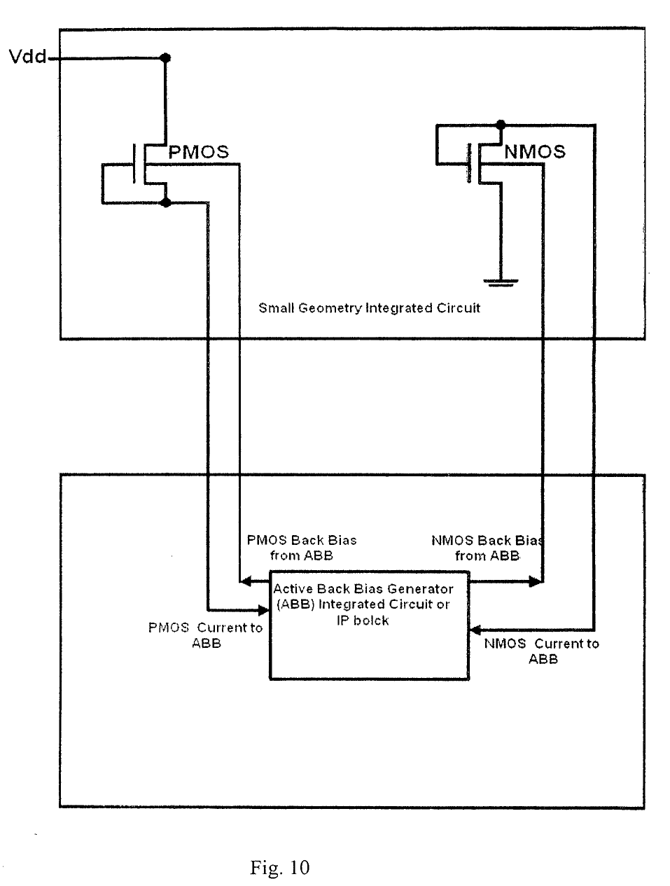

FIG. 11 is a more detailed block diagram of the Active Back Bias Generator.

### DETAILED DESCRIPTION OF PREFERRED EMBODIMENT

An active back bias voltage, applied to one or more wells of N-MOS and/or P-MOS transistors of an integrated circuit, is used to set the threshold voltage or the leakage current of the transistors in the well precisely in order to improve speed by optimizing the Vt or conserving power by controlling the sub-threshold leakage current.

In one embodiment, depending upon the activity of the transistors in a given well for a given period, the back bias generator dynamically modulates the back bias voltage applied to the well to optimize transistor performance based upon a predetermined set of instructions. Typically the instructions optimize the Vt level for speed considerations or minimize the sub-threshold leakage for power saving considerations. Other optimization criteria can be selected. An empirical relationship between Vt and Isub can be employed based upon the particular device and process parameters; a combination of theoretical and empirical relationships is preferred to adjust the back bias level for Vt while measuring or sensing Isub.

The disclosed invention provides a solution to the conventional problems mentioned above. Using active back biasing, the sub-threshold currents can be accurately and even adaptively, versus temperature, voltage, or other parameters, controlled to a prescribed level set by the design engineer.

Additional benefits of actively controlling the back bias are also realized:
a) Improved punch-through voltage
b) Lower effective junction capacitance
c) Better “worst-case” performance
d) Multiple, changeable Vt levels on the same chip without a custom process
e) Many of the effects of IC processing variation are eliminated or minimized.

The invention, termed an “ADOC™” for Active DC Output Control™ technology can be either a separate integrated circuit or an embedded circuit module within a larger integrated circuit. The ADOC™ chip or IC portion precisely controls the well bias of PMOS and NMOS transistors which exhibit undesirable sub-threshold current levels with the bias of the uncompensated integrated circuit. Multiple ADOC™ chips may be used for large IC's or multiple ADOC™ may be embedded in a large IC.

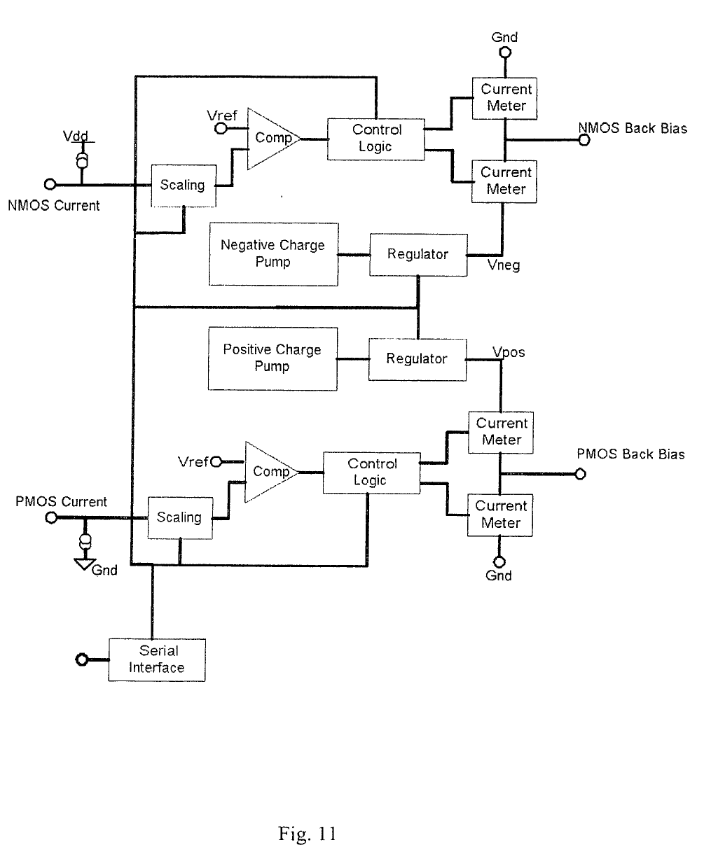

FIG. 11 is a block diagram of the ADOC™ integrated circuit. It contains a serial interface for accepting programming of multiple Vt levels in reprogrammable memory. At least two current sensing capabilities, one for a PMOS well and one for a NMOS well are provided. At least two bias voltage setting capabilities, one for a PMOS well and one for a NMOS well are preset. A “logic” portion for accepting instructions through the serial interface is also provided, allowing the user to choose among Vt levels depending upon the application running on the biased chip, for instance a “sleep mode” versus a fast response mode.

In alternative embodiments one or more Isub levels in combination with one or more Vt levels can be stored and then chosen based upon one or more instructions. Alternatively levels for Isub and Vt can be determined based upon design and process parameters and configured into the circuit at the mask level so that no additional instruction need be given; changing of these levels is then not possible after the fabrication step unless additional circuitry is used.

Leakage reduction is accomplished by monitoring an input, in one case a current from the IC being controlled. The current from the IC must be dependent on the leakage current of devices in the same well, PMOS or NMOS, on the IC. This current will then naturally decrease with increased back bias. The ADOC™ adjusts an output voltage, which is the back bias voltage for the well being monitored, until the current returning from the IC achieves a pre-set value which has been programmed into a circuit element. This voltage is then dynamically maintained about the target voltage that generated the programmed current value. Even when conditions which affect the leakage current change such as temperature, supply voltage, age, etc., the closed-loop ADOC™ function adjusts the back bias voltage until the leakage current is again at the pre-set target. The pre-set target value can be set in the prototype phase using a Summit supplied GUI, graphical user interface. The GUI then issues a code which is used in production to set the current before the part is shipped. If desired, the current can be programmed post the printed circuit board stuffing level using an alternative interface

The ADOC™'s active back bias generator applies a voltage to a well of devices on the small geometry integrated circuit. Wells connected to each other need only one, optimally placed, reference transistor for the active back bias generator to monitor. Unconnected wells require their own reference transistor for a dedicated active back bias generator to monitor. Alternatively when unconnected wells are well characterized such that the back bias to achieve a given Isub, and consequently a certain Vt, in one well is a known function of the back bias to achieve the same parameters in a different well then only one reference transistor is needed. The dynamically applied back bias voltages to the different wells is adjusted based upon the known relationship of the measured reference transistor and the unmonitored wells. The maximum back bias voltage applied is limited based upon theoretical and empirical considerations. “Small geometry” as used here is a relative term and is not meant to be limiting to the invention. In general the benefits of this invention will be realized in integrated circuits with geometries of 0.25 microns and smaller.

In an alternative embodiment one ADOC™ chip or embedded portion is switched between various wells based upon the activity level of the transistors in the well. If the transistors in one well are in a non-active or unpowered state then no ADOC™ control is required and an ADOC™ associated with that well may be switched to dynamically control a powered well.

Foregoing described embodiments of the invention are provided as illustrations and descriptions. They are not intended to limit the invention to precise form described. In particular, it is contemplated that functional implementation of invention described herein may be implemented equivalently in hardware, software, firmware, and/or other available functional components or building blocks. Other variations and embodiments are possible in light of above teachings, and it is thus intended that the scope of invention not be limited by this Detailed Description, but rather by Claims following.

1. A method for actively adjusting the back bias voltage of one or more CMOS transistors comprising the steps:
fabricating a reference transistor on a chip,
monitoring the leakage current of the reference transistor with an active dc output control circuit, and
adjusting the back bias voltage of the well containing the reference transistor until the leakage current is below a preset value.

2. The method of claim 1 wherein said reference transistor comprises a P-MOS transistor in a P-MOS well or a N-MOS transistor in a N-MOS well.

3. The method of claim 1 wherein said monitoring and said adjusting are performed by an active dc output control circuit not on the same chip as the reference transistor.

4. The method of claim 1 wherein said active dc output control circuit monitors and adjusts at least one P-MOS well and at least one N-MOS well.

5. The method of claim 1 wherein there is one or more active dc output control circuits on the same chip with one or more said reference transistors.

6. The method of claim 1 wherein said preset leakage value is determined by the mask design of said active dc output control circuit.

7. The method of claim 1 wherein said preset leakage value is stored in programmable circuit elements of said active dc output control circuit after fabrication.

8. The method of claim 7 wherein said preset leakage value is stored in re-programmable circuit elements of said active dc output control circuit after fabrication.

9. The method of claim 8 wherein said active dc output control circuit processes a signal to set said preset leakage value in said reprogrammable circuit elements of said active dc output control circuit.

10. The method of claim 9 wherein said active dc output control circuit contains re-programmable circuit elements and addressing means for one or more preset leakage values.

11. An integrated circuit for actively adjusting the back bias voltage of one or more CMOS transistors comprising:
a means for monitoring the leakage current of a reference transistor on a chip,
a means for adjusting the back bias voltage of the well containing the reference transistor,
a means for determining when the leakage current is below a preset value, and
a means for maintaining the back bias voltage and the leakage current in a narrow range.

12. The integrated circuit of claim 11 wherein said integrated circuit is not on the same chip as the reference transistor.

13. The integrated circuit of claim 11 wherein said reference transistor comprises a P-MOS transistor in a P-MOS well or a N-MOS transistor in a N-MOS well.

14. The integrated circuit of claim 11 wherein said leakage current preset values are stored in programmable memory.

15. The integrated circuit of claim 11 further comprising a means to adjust the back bias of a well not containing the reference transistor.

16. An integrated circuit for actively adjusting one or more of its output voltages based on monitoring the current of one or more CMOS transistors comprising:
a means for monitoring the current of one or more CMOS transistors,
a means for adjusting one or more of its output voltages,
a means for determining when the monitored one or more currents is below a preset value,
a means for maintaining its one or more output voltages in a narrow range, and
a means for storing the preset values in programmable memory.

17. An integrated circuit for actively adjusting the threshold voltage of one or more CMOS transistors comprising:
a means for monitoring the leakage current of a reference transistor on a chip;
a means for adjusting the back bias voltage of the well containing the reference transistor;
a means for determining when the leakage current is about a preset value;
a means for maintaining the back bias voltage and the leakage current in a narrow range; and
a means for correlating said leakage current with the threshold voltage.
